(19) United States
(12) Patent Application Publication
(10) Pub. No.: US 2010/0230746 A1
(43) Pub. Date: Sep. 16, 2010

(54) SEMICONDUCTOR DEVICE AND MANUFACTURING METHOD THEREOF

(75) Inventors: Hironori AOKI, Niiza-shi (JP); Shuichi Kaneko, Niiza-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Sanken Electric Co., Ltd., Niiza-shi (JP)

(21) Appl. No.: 12/649,953

(22) Filed: Dec. 30, 2009

(30) Foreign Application Priority Data
Mar. 13, 2009 (JP) 2009-061155

(51) Int. Cl. H01L 29/78; H01L 21/336

(52) U.S. Cl. 257/330; 438/270; 257/E21.41; 257/E29.257

(57) ABSTRACT

A semiconductor device includes an epitaxial layer having a first conduction type, a base layer formed adjacent and on the epitaxial layer and having an opposite second conduction type to the first conduction type, a source layer formed selectively on the base layer and having the first conduction type, a trench which passes through the base layer and the source layer and which reaches the epitaxial layer, an insulation film formed along an interior wall of the trench, a control electrode formed within the trench via the insulation film, and a semiconductor region formed along the bottom part of the trench at the epitaxial layer and having the first conduction type.

### CROSS REFERENCE TO RELATED APPLICATION

This application is based upon and claims the benefit of priority from the prior Japanese Patent Application No. 2009-061155 filed on Mar. 13, 2009, the entire contents of which is incorporated herein by reference.

### BACKGROUND OF THE INVENTION

1. Field of the Invention

The present invention is related to a semiconductor device and a manufacturing method thereof, and in particular, is related to a semiconductor device having a trench gate and a manufacturing method thereof.

2. Description of the Related Art

FIG. 10 is a cross-sectional diagram that shows a structure of a conventional trench gate type power MOSFET.

A conventional trench gate type power MOSFET is arranged with an n− type epitaxial layer 1 which is formed on an n+ type substrate, a p type base layer 2 formed on this epitaxial layer 1 and an n+ type source layer 3 formed on this base layer 2. Also, this trench gate type power MOSFET is further arranged with a trench 4 which is formed in a stripe shape viewed in a planar direction, and which is formed so that it goes through the base layer 2 and a source layer 3 and reaches the epitaxial layer 1, a gate electrode 6 formed via a gate insulation film 5 within this trench 4, an interlayer insulation film 7 formed on the gate electrode 6, a source electrode 8 formed to connect with the base layer 2 and the source layer 3 and a drain electrode 9 formed to connect with the epitaxial layer 1.

A manufacturing method of a conventional trench gate type power MOSFET is as follows.

The epitaxial layer 1 is grown on a substrate not shown in the diagram using a known CVD (Chemical Vapor Deposition) method. Boron (B) is implanted into the epitaxial layer 1 using an ion implantation method, the boron is activated and the base layer 2 is formed. Arsenic (As) is implanted into the base layer 2 using the ion implantation method, the arsenic is activated and the source layer 3 is formed.

Next, a mask formed via an oxide film is formed on the base layer 2 and source layer 3. The trench 4 is formed to pass through the base layer 2 and source layer 2 and reach the epitaxial layer 1 using the mask and reactive ion etching (RIE). The trench has a width of 0.4 μm to 1.0 μm for example. Next, a sacrificial oxide film not shown in the diagram is formed within the trench 4 using a thermal oxidation method. After removing this sacrificial oxide film, a gate oxide film 5 is formed within the trench 4 again using the thermal oxidation method. Poly-silicon is buried into the trench 4 via the gate oxide film 5 using the CVD method, and a gate electrode 6 is formed from this poly-silicon. Next, an interlayer insulation film 7 is formed on the gate electrode 6 and a source electrode 8 and drain electrode 9 are formed on this interlayer insulation film 7 using a deposition method.

In a conventional trench gate type power MOSFET, because a channel (current path) is formed along the exterior wall of the trench 4, it is possible to increase cell density compared to a planar type power MOSFET. Furthermore, ON resistance (Ron) decreases when an n+ type semiconductor layer is formed at the bottom part of the trench 4, as disclosed in Japanese Laid Open Patent 2000-299464 (patent document).

However, high voltage resistance was not obtained in the trench gate type power MOSFET, though the ON resistance was improved, sufficient. This type of problem is present not only in the power MOSFET with the structure disclosed in the above stated patent document but also in a trench gate type IGBT.

### SUMMARY OF THE INVENTION

The present invention was invented to solve the above stated problems. The present invention provides a semiconductor device and a manufacturing method thereof having a trench gate structure which simultaneously achieves both high voltage resistance and ON resistance stability.

In order to solver the above stated problems, a first characteristic of an embodiment related to the present invention is a semiconductor device including an epitaxial layer having a first conduction type, a base layer formed adjacent and on the epitaxial layer and having an opposite second conduction type to the first conduction type, a source layer formed selectively on the base layer and having the first conduction type, a trench which passes through the base layer and the source layer and which reaches the epitaxial layer, an insulation film formed along an interior wall of the trench, a control electrode formed within the trench via the insulation film, and a semiconductor region formed along the bottom

In addition, a second characteristic related to an embodiment of the present invention is a manufacturing method of a semiconductor device, the method including forming a base layer by implanting second type conduction impurities into a first conduction type epitaxial layer using an ion implantation method, forming a source layer by implanting first type conduction impurities into the base layer by the ion implantation method, forming a trench to pass through the base layer and the source layer and to reach the epitaxial layer, forming a first oxide film within the trench, and forming a first conduction type semiconductor region by implanting first type conduction impurities using an ion implantation method into a bottom part of the trench after forming the first oxide film.

### BRIEF DESCRIPTION OF THE DRAWINGS

FIG. 1 is a planar view diagram of a semiconductor device having a trench gate structure related to an embodiment of the present invention.

FIG. 2 is a cross-sectional diagram along the line A-A of the semiconductor device related to an embodiment.

FIG. 3 to FIG. 7 are process cross-sectional diagrams for explaining a manufacturing method of the semiconductor device related to an embodiment.

FIG. 8 is a correlation diagram that shows the relationship between ON resistance (Ron) and a drain voltage (Vds) of a semiconductor having a trench gate structure.

FIG. 9 is a planar view diagram of the semiconductor device having a trench gate structure related to a transformation example of an embodiment of the present invention.

FIG. 10 is a cross-sectional diagram of a structure of a conventional trench gate type power MOSFET.

### DETAILED DESCRIPTION OF THE INVENTION

The invention will be described with reference to the attached drawings. Like or corresponding parts are denoted by like or corresponding reference numerals. The drawings are schematic, and may sometimes differ from actual components. Further, dimensions and ratios of components may be different between drawings.

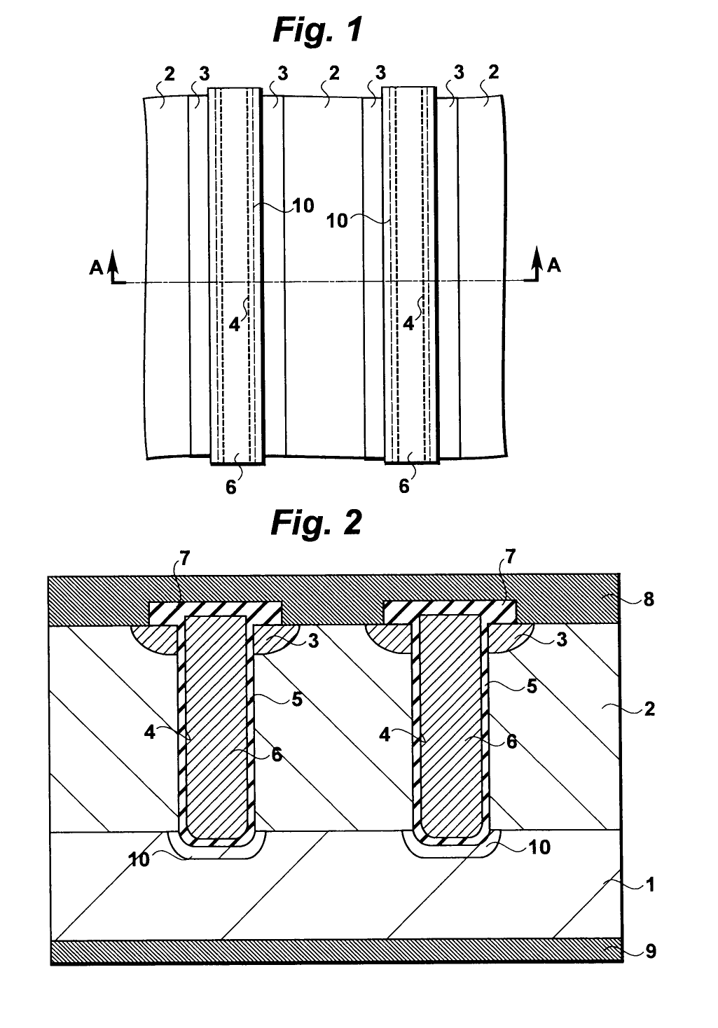

FIG. 1 is a planar view diagram of a semiconductor device having a trench gate structure related to an embodiment of the present invention, and FIG. 2 is a cross-sectional diagram along the line A-A of the semiconductor device shown in FIG. 1.

The semiconductor device having a trench gate structure in the present embodiment is a trench gate type power MOSFET (Metal Oxide Field Effect Transistor). This trench gate type power MOSFET is arranged with an n+ type substrate not shown in the diagram, an n− type epitaxial layer 1 which is formed on this substrate, a p type base layer 2 formed on this epitaxial layer 1 and an n+ type source layer 3 formed on this base layer 2. Furthermore, this trench gate type power MOSFET is further arranged with a trench 4 which is formed in a stripe shape viewed in a planar direction, and which is formed so that it goes through the base layer 2 and a source layer 3 and reaches the epitaxial layer 1, a gate electrode 6 formed via a gate insulation film 5 within this trench 4, an interlayer insulation film 7 formed on the gate electrode 6, a source electrode 8 formed to connect with the base layer 2 and the source layer 3, and a drain electrode 9 formed to connect with the epitaxial layer 1. Also, this trench gate type power MOSFET is arranged with an n− type semiconductor layer (semiconductor region) 10 formed along bottom part of the trench 4 in the epitaxial layer 1 so as to be adjacent to the base layer 2 and also has the same concentration of impurities as the epitaxial layer 1. In other words, the concentration of impurities of the n− type semiconductor layer 10 and the epitaxial layer 1 is low compared to the concentration of impurities of the source layer 3.

The bottom part of the trench 4 is set deeper than the bottom surface (pn junction surface with the epitaxial layer 1) of the base layer 2. Therefore, the n− type semiconductor later 10 is formed in a deeper position than the base layer 2. In the present embodiment, the n− type semiconductor layer 10 is formed deeper than the base layer 2, along the bottom surface of the trench 4 and in a cross sectional crevice shape.

The gate electrode 6 projects out from the surface of the base layer 2 and the source layer 3 and may also be formed so as to eat into the interlayer insulation film 7.

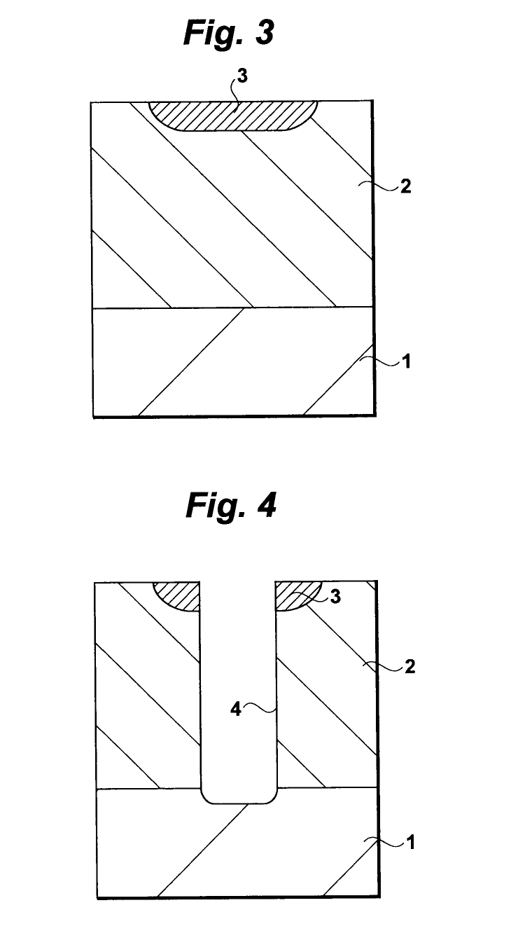

FIG. 3 to FIG. 7 are process cross-sectional diagrams for explaining a manufacturing method of the semiconductor device (trench gate type power MOSFET) related to an embodiment.

First, the epitaxial layer 1 is grown on the substrate not shown in the diagram using a known CVD (Chemical Vapor Deposition) method. Boron (B) is implanted into almost the entire surface of the epitaxial layer 1 using an ion implantation method, the boron is activated and the base layer 2 is formed on the epitaxial layer 1. Next, arsenic (As) is selectively implanted into the base layer 2 using the ion implantation method, the arsenic is activated and the source layer 3 is formed in an island shape on the base layer 2. Here, the concentration of n type impurities in the epitaxial layer 1 is set at 1×10¹⁴ cm⁻³ to 1×10¹⁵ cm⁻³ and the thickness of the epitaxial layer 1 is set at 30 μm to 50 μm. The concentration of n type impurities in the base layer 2 is set at 5×10¹⁶ cm⁻³ to 5×10¹⁷ cm⁻³ and the thickness of the base layer 2 is set at 1.0 μm to 1.5 μm.

Next, a mask not shown in the diagram is formed via an oxide film for example on the base layer 2 and the source layer 3. Following this, a desired trench 4 is formed to pass through the base layer 2 and the source layer 3 and reach the epitaxial layer 1 using the mask and reactive ion etching (RIE). In the present embodiment, the width of the trench 4 is set at 0.4 μm to 1.0 μm and the depth from the surface of the base layer 2 is set at 1.0 μm to 2.0 μm. In addition, the trench 4 in the present embodiment has a cross-sectional taper shaped interior wall having an inner angle within a range of 60° to 89° with respect to the bottom surface. By appropriately selecting the shape of the mask and type of etching gas which includes fluorine (F) or chlorine (Cl) in the reactive ion etching, it is possible to easily obtain a cross-sectional shape of the trench 4.

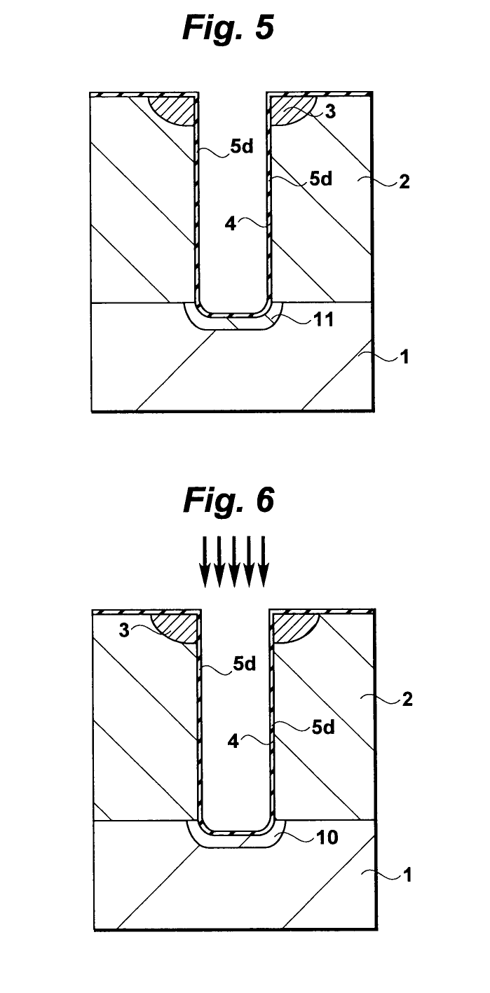

Next, a sacrificial oxide film 5d (first oxide film) is formed on an interior wall of the trench 4 using a thermal oxidation method in order to remove damage of the reactive ion etching (refer to FIG. 5). Because p type impurities included in the base layer 2 diffuse (out diffusion is generated) and mix within the epitaxial layer 1 from the side wall of the trench 4 at the same time as the process for forming the sacrificial oxide film 5d using this thermal oxidation method, a p type inversion layer 11 is formed on the surface part of the epitaxial layer 1 which is exposed from the bottom part of the trench 4 (refer to FIG. 5)

Next, n type impurities such as phosphorus (P) or arsenic (As) are implanted into the trench 4 using an ion implantation method. These n type impurities are implanted in a perpendicular direction with respect to the bottom part of the trench 4, and also implanted into the surface part of the epitaxial layer 1 via the sacrificial oxide layer 5d. By activating these n type impurities using thermal diffusion the conduction of the p type inversion layer 11 is again inverted and an n− type semiconductor layer 10 is formed (refer to FIG. 6). At this time, the amount of n type impurities which are ion implanted is determined by the concentration and depth of the inversion layer 11 and the concentration of impurities of the n− type semiconductor layer 10 is set to be the same as the concentration of impurities in the epitaxial layer 1. The process for activating the n type impurities may be performed at the same time as the subsequent thermal oxidation process for forming the gate oxide film 5 and may also be performed after the thermal oxidation process.

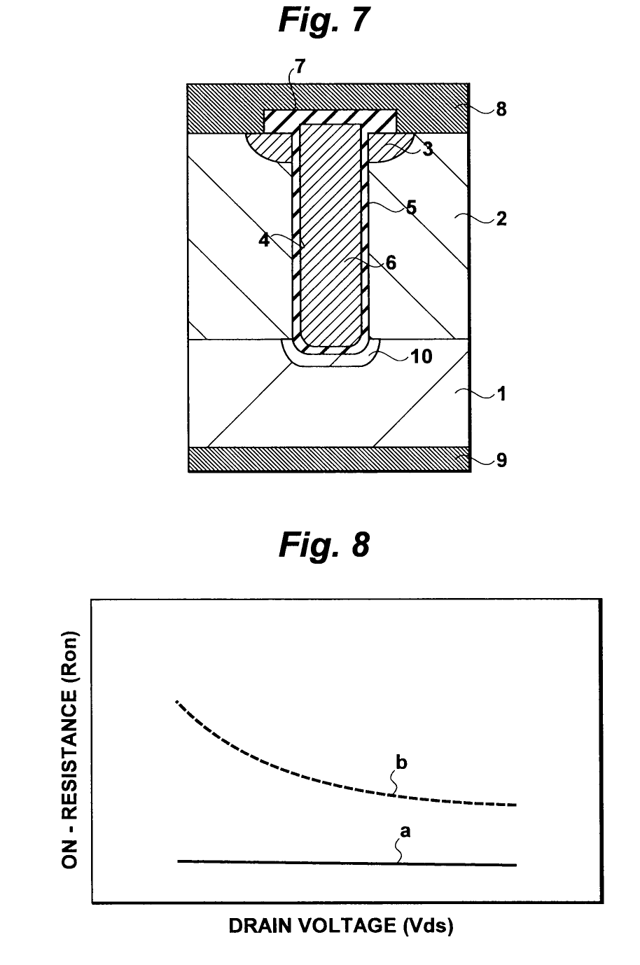

Next, the sacrificial oxide film 5d is removed using a wet etching method which uses a fluorine hydroxide (HF) solution for example, and following this, a thermal oxidation process is performed, and the gate oxide layer 5 is formed on the bottom surface and interior wall of the trench 4 (refer to FIG. 7). Following this, the gate electrode 6 is formed by burying poly-silicon into the trench 4 using chemical vapor deposition (CVD). Then, the interlayer insulation film 7 is formed on the gate electrode 6 and the source electrode 8 is formed using a deposition method. Following this, the drain electrode 9 is formed on opposite surface to the base layer 2 of the epitaxial layer 1 (refer to FIG. 7) and the semiconductor device related to the present embodiment is complete.

Here, in a conventional trench gate type power MOSFET, it is necessary to set a low concentration of impurities of about 1×10¹⁴ cm⁻³ to 1×10¹⁵ cm⁻³ in order to achieve a high voltage resistance of about 600 V for example. In this case, the above stated high voltage resistance can be obtained, however, as shown by the actual line b in FIG. 8, variation in ON resistance (Ron) is generated which is dependent on the drain voltage (Vds).

The phenomenon whereby this ON resistance (Ron) is dependent on the drain voltage (Vds) is caused when, as stated above, a p type inversion layer 11 is formed along the bottom part of the trench 4 in the epitaxial layer 1 and the current which flows between the source and drain flows via the pn junction which is produced by p type inversion layer 11 and the epitaxial layer 1. The influence of this type of drain voltage (Vds) is at its highest in the case where the p type inversion layer 11 is adjacent to the base layer 2.

In addition, the p type inversion layer 11 is formed in a thermal oxidation process for forming the sacrificial oxide film 5d or the gate oxide film 5 by the following mechanism. In the thermal oxidation process, because it is difficult for oxidation gas that is supplied to the substrate to reach as far as the bottom part of the trench 4, the growth of the oxide film on the bottom part of the trench 4 is suppressed. As a result, the p type impurities included in the base layer 2 undergo out diffusion, become mixed at the bottom part of the trench 4 and an auto doping phenomenon is easily produced. In particular, in a trench gate type power MOSFET which has a high resistance structure, the concentration of impurities in the epitaxial layer 1 is set low in order to secure resistance at the pn junction of the epitaxial layer 1 and base layer 2, and the conduction in one part of the surface part of the epitaxial layer 1 at the bottom part of the trench 4 is inverted by auto doping and the p type inversion layer 11 is easily formed.

Because an epitaxial layer 1 with a low concentration of impurities is basically used in the trench gate type power MOSFET related to the present embodiment, it is possible to realize high voltage resistance. Furthermore, because an n− type semiconductor layer 10 is formed on the epitaxial layer 1 at the bottom part of the trench 4 in the trench gate type power MOSFET related to the present embodiment, it is possible to again invert the p type inversion layer 11 to an n type and therefore ON resistance (Ron) is not dependent on the drain voltage (Vgs) as is shown in the actual line a in FIG. 8 and it is possible to obtain stability in switching characteristics. Also, because the concentration of impurities in the n− type semiconductor layer 10 is set the same as the concentration of impurities in the epitaxial layer 1, it is possible to secure a conventional high voltage resistance.

In addition, in the manufacturing method related to the present embodiment, because the n− type semiconductor layer 10 is formed by implanting n type impurities using an ion implantation method which has a higher controllability of the concentration of impurities than a solid-phase diffusion method after the p type inversion layer 11 is formed, it is possible to manufacture a trench gate type power MOSFET in which high voltage resistance and stable ON resistance can be simultaneously realized.

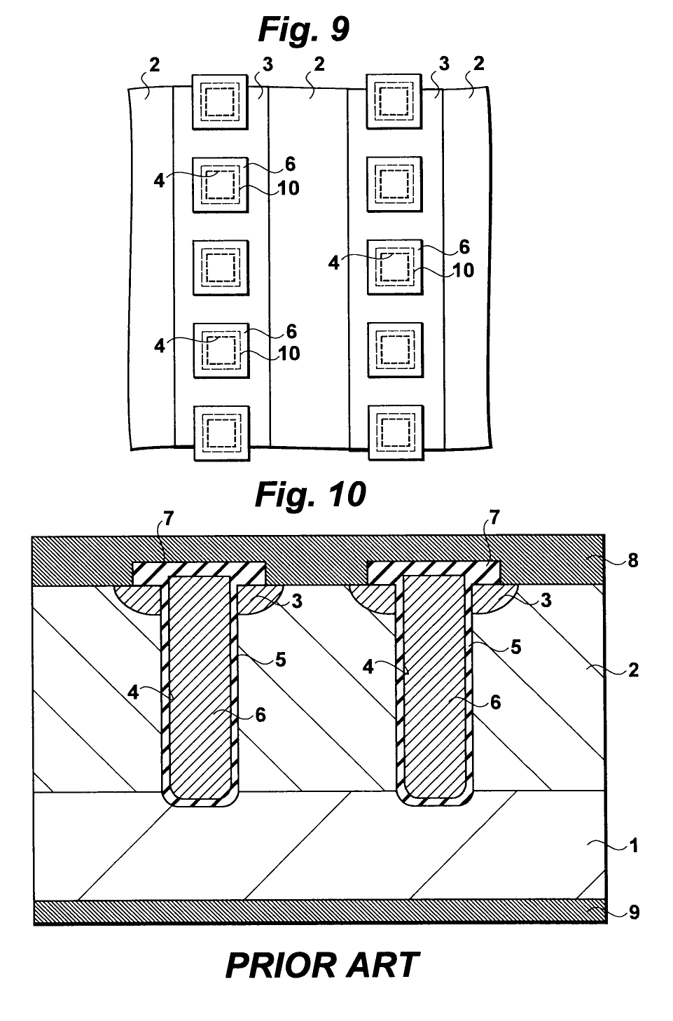

Furthermore, in the present invention, a trench 4 which has narrow width dimensions according to process rules and the electrical characteristics demanded by the semiconductor device can also be applied to a trench gate type power MOSFET arranged with a column shaped trench 4 interior as is shown in FIG. 9. In this type of trench gate type power MOSFET, because the aperture of the trench 4 is small and the supply of an oxidation gas to the interior of the trench 4 becomes smaller, the growth of the gate oxide film 5 is further suppressed and the auto doping phenomenon is more easily produced. However, according to the manufacturing method related to the present embodiment, because it is possible to form with certainty the n− type semiconductor layer 10 at an appropriate concentration of impurities at the bottom part of the trench 4 using an ion implantation method, it is possible to simultaneously realize high voltage resistance and stable ON resistance of the trench gate type power MOSFET.

### Other Embodiments

As stated above, the present invention is described by a plurality of embodiments. However, the descriptions and diagram which form one part of this disclosure are not limited to this invention. The present invention can be applied to various alternative embodiments, and examples within the scope of the present invention and the scope of the patent claims.

For example, the present invention can also be applied to a trench gate type MISFET (Metal Insulator Field Effect Transistor) having a nitride film other than an oxide film or a composite film of an oxide film and a nitride film, or an oxynitride film used as a gate insulation film instead of the gate oxide film 5

In addition, the present invention can also be applied to an IGBT having a p type semiconductor layer between the epitaxial layer 1 and the drain electrode 9. In addition, the present invention can also be applied to a semiconductor device comprised from, for example, a p channel type trench gate type MOSFET in which the conduction of each layer is inverted. Further, the present invention can also be applied in the case where defective layers are formed on the bottom of the trench 4 due to reasons other than auto doping.

What is claimed is:

1. A semiconductor device comprising:
an epitaxial layer having a first conduction type;
a base layer formed adjacent and on the epitaxial layer and having an opposite second conduction type to the first conduction type;
a source layer formed selectively on the base layer and having the first conduction type;
a trench which passes through the base layer and the source layer and which reaches the epitaxial layer;
an insulation film formed along an interior wall of the trench;
a control electrode formed within the trench via the insulation film; and
a semiconductor region formed along the bottom part of the trench at the epitaxial layer and having the first conduction type.

2. The semiconductor device according to claim 1, wherein the semiconductor region has the same concentration of impurities as the epitaxial layer.

3. The semiconductor device according to claim 1, wherein the concentration of impurities of the semiconductor region and the epitaxial layer is lower compared to the concentration of impurities of the source layer.

4. The semiconductor device according to claim 2, wherein the concentration of impurities of the semiconductor region and the epitaxial layer is lower compared to the concentration of impurities of the source layer.

5. The semiconductor device according to claim 1, wherein the bottom part of the trench is formed deeper from the base layer and the semiconductor region is arranged in a deeper position than the base layer.

6. The semiconductor device according to claim 4, wherein the bottom part of the trench is formed deeper from the base layer and the semiconductor region is arranged in a deeper position than the base layer.

7. The semiconductor device according to claim 1, wherein a side wall of the trench has a taper shape.

8. A method of manufacturing a semiconductor device, the method comprising;
forming a base layer by implanting second type conduction impurities into a first conduction type epitaxial layer using an ion implantation method;
forming a source layer by implanting first type conduction impurities into the base layer by the ion implantation method;
forming a trench to pass through the base layer and the source layer and to reach the epitaxial layer;
forming a first oxide film within the trench; and
forming a first conduction type semiconductor region by implanting first type conduction impurities using an ion implantation method into a bottom part of the trench after forming the first oxide film.

9. The method of manufacturing a semiconductor device according to claim 8, further comprising removing the first oxide film after implanting the first type conduction impurities into the semiconductor region.

10. The method of manufacturing a semiconductor device according to claim 9, wherein the first oxide film is a sacrificial oxide film.

11. The method of manufacturing a semiconductor device according to claim 8, further comprising forming a second oxide film within the trench after removing the first oxide film.

12. The method of manufacturing a semiconductor device according to claim 11, wherein the second oxide film is a gate insulation film.
